(19) United States
(12) Patent Application Publication
(10) Pub. No.: US 2024/0423070 A1
(43) Pub. Date: Dec. 19, 2024

(54) DISPLAY DEVICE

(71) Applicant: Samsung Display Co., Ltd., Yongin-si (KR)

(72) Inventors: JUNGHYUN KWON, Yongin-si (KR); SEON-TAE YOON, Yongin-si (KR); Soonkyu CHA, Yongin-si (KR)

(73) Assignee: Samsung Display Co., Ltd., Yongin-si (KR)

(21) Appl. No.: 18/658,107

(22) Filed: May 8, 2024

(30) Foreign Application Priority Data
Jun. 16, 2023 (KR) 10-2023-0077177

(51) Int. Cl. H10K 59/80; H10K 59/122

(52) U.S. Cl. CPC H10K 59/879; H10K 59/122; H10K 59/873

(57) ABSTRACT

A display device includes a first display substrate including a first base layer including a display area and a non-display area adjacent to the display area, and a second display substrate including a second base layer including pixel areas overlapping the display area in a plan view and a peripheral area surrounding the pixel areas. The first display substrate further includes light emitting elements respectively overlapping the pixel areas in a plan view, an encapsulation layer including a first inorganic layer covering the light emitting elements, an organic layer disposed on the first inorganic layer, and a second inorganic layer disposed on the organic layer, a bank disposed on the encapsulation layer and including openings respectively overlapping the pixel areas in a plan view, and light control patterns respectively disposed in the openings. The second inorganic layer has a first refractive index in a range of about 1.3 and to about 1.46.

This application claims priority to and benefits of Korean Patent Application No. 10-2023-0077177 under 35 U.S.C. § 119, filed on Jun. 16, 2023, in the Korean Intellectual Property Office (KIPO), the entire contents of which are incorporated herein by reference.

### BACKGROUND

### 1. Technical Field

The disclosure relates to a display device including two display substrates coupled with each other and quantum dots and provided with improved color mixture.

### 2. Description of the Related Art

As a display panel, an emissive type display panel that generates a light by itself and emits the light and a transmissive type display panel that transmits a source light generated by a light source after changing optical properties of the source light are widely used. Quantum dots are used to change the optical properties of the source light in the transmissive type display panel.

### SUMMARY

The disclosure provides a display device including two display substrates that are vacuum-bonded with each other and preventing a color mixture phenomenon that occurs between pixels to improve color characteristics.

According to an embodiment of the disclosure, a display device may include a first display substrate including a first base layer including a display area and a non-display area adjacent to the display area, and a second display substrate including a second base layer including pixel areas overlapping the display area in a plan view and a peripheral area surrounding the pixel areas.

The first display substrate may further include light emitting elements respectively overlapping the pixel areas in a plan view, an encapsulation layer including a first inorganic layer covering the light emitting elements, an organic layer disposed on the first inorganic layer, and a second inorganic layer disposed on the organic layer, a bank disposed on the encapsulation layer and including openings defined respectively overlapping the pixel areas in a plan view, and light control patterns respectively disposed in the openings.

The second inorganic layer may have a first refractive index in a range of about 1.3 to about 1.46.

The organic layer may have a second refractive index greater than the first refractive index.

The second refractive index may be in a range of about 1.5 to about 1.7.

A thickness of the second inorganic layer may be in a range of about 400 nm to about 2000 nm.

The second inorganic layer may further include a plurality of layers, one of the plurality of layers may have the first refractive index, and others of the plurality of layers may have a refractive index different from the first refractive index.

The others of the plurality of layers may have a refractive index greater than the first refractive index.

The light emitting elements may emit a blue light.

One of the light control patterns may include an organic material including a metal oxide.

Another one of the light control patterns may include a quantum dot.

The second display substrate may be disposed above the first display substrate.

The display device may further include a filling member filled between the first display substrate and the second display substrate.

The display device may further include a sealing member overlapping the non-display area in a plan view and disposed between the first display substrate and the second display substrate.

The second display substrate may further include a low refractive index layer disposed under the second base layer.

The second display substrate may further include a second capping layer disposed under the low refractive index layer and covering the low refractive index layer.

The display device may further include a first capping layer covering the bank and the light control patterns.

The second inorganic layer may include a silicon oxide.

The second inorganic layer may include a silicon oxynitride.

The second display substrate may further include color filters disposed on the second base layer.

The color filters may include a first color filter, a second color filter, and a third color filter.

Two or more of the first, second, and third color filters may overlap with each other in a plan view in the peripheral area.

According to the above, the refractive index of the second inorganic layer is controlled to prevent the light generated from a light emitting layer from traveling to another pixel adjacent thereto. Thus, the color characteristics of the display device is improved.

### BRIEF DESCRIPTION OF THE DRAWINGS

The above and other advantages of the disclosure will become readily apparent by reference to the following detailed description when considered in conjunction with the accompanying drawings wherein:

FIG. 1 is a perspective view of a display device according to an embodiment of the disclosure;

FIG. 2 is a schematic cross-sectional view of a display device according to an embodiment of the disclosure;

FIG. 3 is a plan view of a display substrate according to an embodiment of the disclosure;

FIG. 4 is an enlarged plan view of a display area according to an embodiment of the disclosure;

FIG. 5 is a schematic cross-sectional view of a display device taken along line I-I′ of FIG. 4;

FIG. 6 is a schematic cross-sectional view of a display device according to an embodiment of the disclosure;

FIG. 7 is a schematic cross-sectional view of a display device according to a comparative example;

FIG. 8 is a graph illustrating an intensity of a light according to wavelengths.; and

FIG. 9 is a schematic cross-sectional view of a second inorganic layer and an organic layer according to an embodiment of the disclosure.

### DETAILED DESCRIPTION OF THE EMBODIMENTS

The disclosure may be variously modified and realized in many different forms, and thus specific embodiments will be illustrated in the drawings and described in detail hereinbelow. However, the disclosure should not be limited to the specific disclosed forms, and be construed to include all modifications, equivalents, or replacements included in the spirit and scope of the disclosure.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure will be described with reference to accompanying drawings.

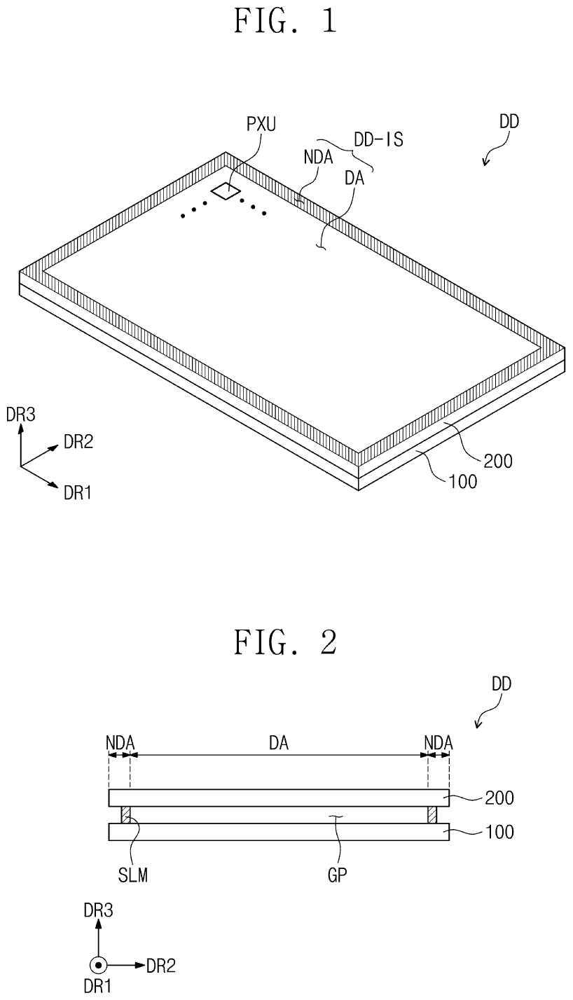

FIG. 1 is a perspective view of a display device DD according to an embodiment of the disclosure. FIG. 2 is a schematic cross-sectional view of the display device DD according to an embodiment of the disclosure.

Referring to FIG. 1, the display device DD may include a display surface DD-IS to display an image through a front surface thereof. The display device DD may display an image through the display surface DD-IS, which is substantially parallel to a plane defined by a first direction DR1 and a second direction DR2 intersecting the first direction DR1, toward a third direction DR3. The third direction DR3 may intersect each of the first direction DR1 and the second direction DR2, and a normal line direction of the display surface DD-IS may be substantially parallel to the third direction DR3. The image displayed through the display surface DD-IS may include a still image as well as a video.

In the embodiment, front (or upper) and rear (or lower) surfaces of each component of the display device DD may be defined with respect to a direction in which the image is displayed. The front and rear surfaces may be opposite to each other in the third direction DR3. Directions indicated by the first, second, and third directions DR1, DR2, and DR3 are relative to each other, and thus, the directions indicated by the first, second, and third directions DR1, DR2, and DR3 may be changed to other directions.

The display device DD may include a display area DA and a non-display area NDA. Unit pixels PXU may be arranged in the display area DA, and the unit pixels PXU may emit a light in response to electrical signals to display the image through the display area DA. The unit pixels PXU may not be arranged in the non-display area NDA. The non-display area NDA may be defined along an edge of the display surface DD-IS and may surround the display area DA.

The display device DD may be activated in response to electrical signals. The display device DD may include various embodiments. For example, the display device DD may be applied to a large-sized electronic item, such as a television set, an outdoor billboard, etc., and a small and medium-sized electronic item, such as a mobile phone, a tablet computer, a navigation unit, a game unit, etc. However, the disclosure is not limited thereto, and the display device DD may be applied to other electronic devices as long as they do not depart from the spirit and scope of the disclosure.

The display device DD may be flexible. The term “flexible” used herein refers to the property of being able to be bent from a structure that is completely bent to a structure that is bent at the scale of a few nanometers. For example, the display device DD may be a curved display device or a foldable display device. According to an embodiment, the display device DD may be rigid.

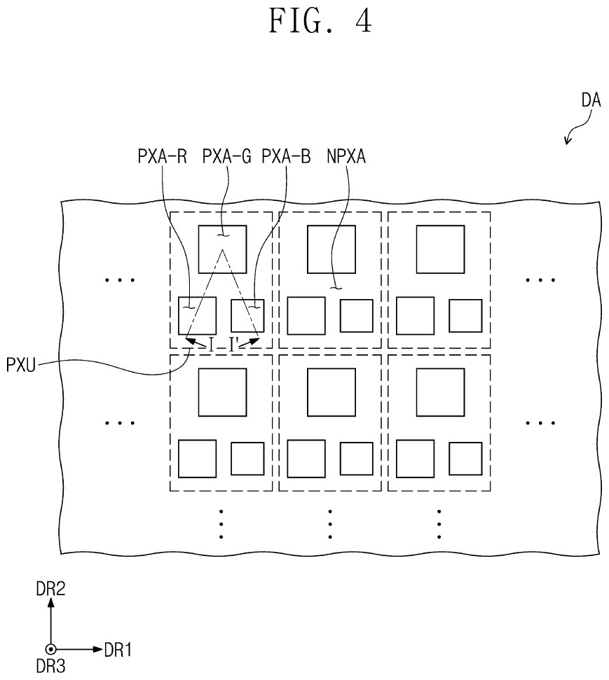

Referring to FIG. 1, the unit pixels PXU may be arranged in rows and columns in the display device DD. The unit pixel PXU may be the smallest repeating unit, and one unit pixel PXU may include at least one pixel area PXA-R, PXA-G, and PXA-B (refer to FIG. 4). According to an embodiment, one unit pixel PXU may include multiple pixel areas PXA-R, PXA-G, and PXA-B (refer to FIG. 4) that provide lights having different colors.

Referring to FIG. 2, the display device DD may include a first display substrate 100 and a second display substrate 200. The second display substrate 200 may be disposed spaced apart upward (e.g., in the third direction DR3) from the first display substrate 100.

A cell gap GP may be a space defined between the first display substrate 100 and the second display substrate 200, which are spaced apart from each other. The cell gap GP may be maintained by a sealing member SLM.

The sealing member SLM may be disposed between the first display substrate 100 and the second display substrate 200 and may overlap the non-display area NDA in a plan view. In a plan view, the sealing member SLM may be aligned with (or disposed adjacent to) an edge of the second display substrate 200, however, the disclosure should not be limited thereto or thereby. The sealing member SLM may hold the second display substrate 200 and the first display substrate 100 so that the second display substrate 200 and the first display substrate 100 are spaced apart from each other by a distance (e.g., a predetermined distance) and may prevent external oxygen and moisture from entering the second display substrate 200 and the first display substrate 100.

The sealing member SLM may include a binder resin and inorganic fillers mixed with the binder resin. The sealing member SLM may further include other additives. The additives may include an amine-based curing agent and a photoinitiator. The additives may further include a silane-based additive and an acrylic-based additive. The sealing member SLM may include an inorganic-based material such as a frit.

FIGS. 1 and 2 show the structure in which areas of surfaces of the first display substrate 100 and the second display substrate 200, which face each other in the third direction DR3, are the same in a plan view, however, the disclosure should not be limited thereto or thereby.

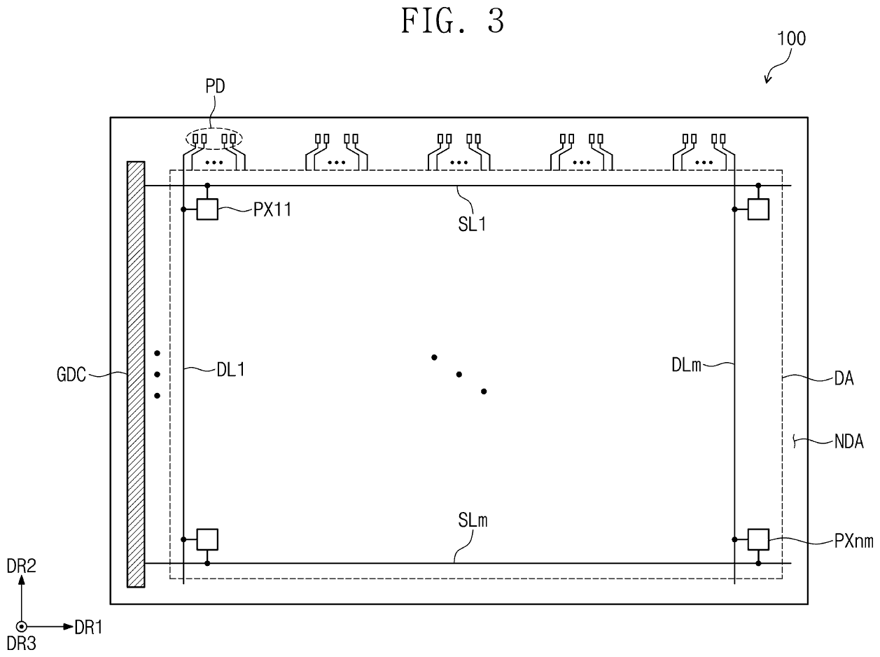

FIG. 3 is a plan view of the first display substrate 100 according to an embodiment of the disclosure, and FIG. 4 is an enlarged plan view of a display area according to an embodiment of the disclosure.

Referring to FIG. 3, the first display substrate 100 may include signal lines SL1 to SLn and DL1 to DLm and pixels PX11 to PXnm The signal lines SL1 to SLn and DL1 to DLm may include multiple gate lines SL1 to SLn and multiple data lines DL1 to DLm. Each of the pixels PX11 to PXnm may be connected to a corresponding gate line of the gate lines SL1 to SLn and a corresponding data line of the data lines DL1 to DLm.

Each of the pixels PX11 to PXnm may include a pixel driving circuit and a light emitting element. More types of signal lines may be provided in the first display substrate 100 depending on the configuration of the pixel driving circuit of the pixels PX11 to PXnm.

A gate driving circuit GDC may be integrated in the first display substrate 100 through an oxide silicon gate driver circuit (OSG) process or an amorphous silicon gate driver circuit (ASG) process. The gate driving circuit GDC connected to the gate lines SL1 to SLn may be disposed on a side of the non-display area NDA in the first direction DR1. Pads PD connected to one ends of the data lines DL1 to DLm may be disposed on a side of the non-display area NDA in the second direction DR2.

Referring to FIG. 4, the unit pixels PXU may be arranged in the first direction DR1 and the second direction DR2. In an embodiment, the unit pixel PXU may include a first pixel area PXA-R, a second pixel area PXA-G, and a third pixel area PXA-B, which emit lights having different colors. The first pixel area PXA-R, the second pixel area PXA-G, and the third pixel area PXA-B may emit a red light, a green light, and a blue light, respectively.

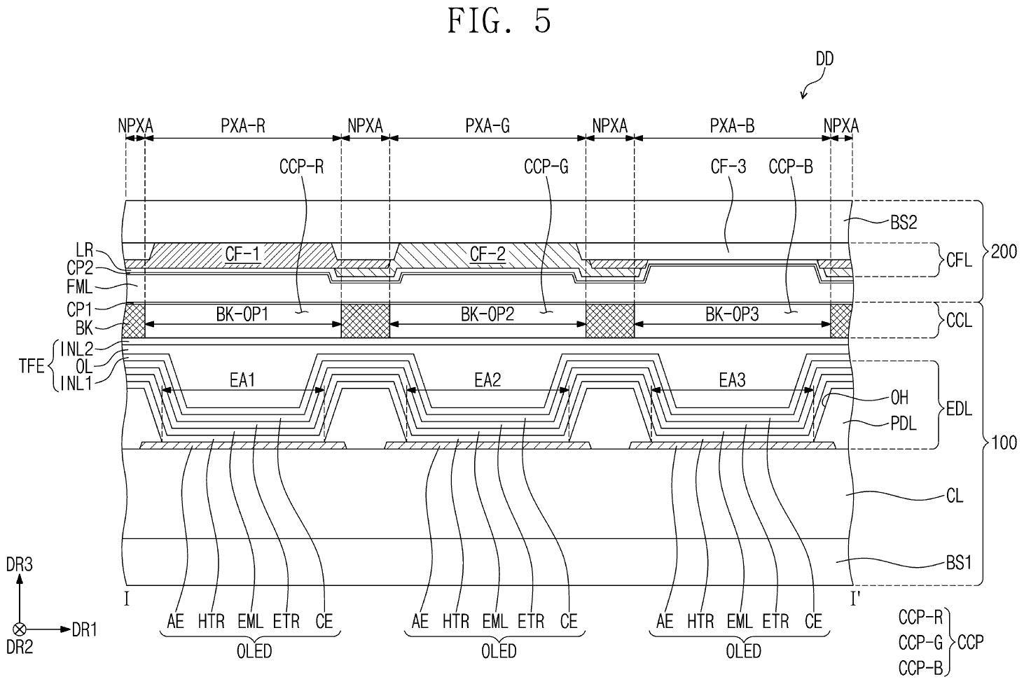

The first pixel area PXA-R, the second pixel area PXA-G, and the third pixel area PXA-B may be defined with respect to the second display substrate 200 (refer to FIG. 5). A peripheral area NPXA (refer to FIG. 5) may be defined between the first, second, and third pixel areas PXA-R, PXA-G, and PXA-B. The peripheral area NPXA may define a boundary of the first, second, and third pixel areas PXA-R, PXA-G, and PXA-B and may prevent a color mixture between the first, second, and third pixel areas PXA-R, PXA-G, and PXA-B.

Among the pixels PX11 to PXnm (refer to FIG. 3) of the first display substrate 100 (refer to FIG. 3), in a plan view a pixel overlapping the first pixel area PXA-R of the second display substrate 200 (refer to FIG. 5) may be defined as a first pixel, a pixel overlapping the second pixel area PXA-G of the second display substrate 200 (refer to FIG. 5) may be defined as a second pixel, and a pixel overlapping the third pixel area PXA-B of the second display substrate 200 (refer to FIG. 5) may be defined as a third pixel. However, as described below, the first pixel, the second pixel, and the third pixel may have substantially the same configuration without being distinguished from each other. The first pixel, the second pixel, and the third pixel may not be distinguished from each other and may be merely defined as pixels respectively overlapping the first pixel area PXA-R, the second pixel area PXA-G, and the third pixel area PXA-B.

Each of the first pixel, the second pixel, and the third pixel may include a light emitting element OLED (refer to FIG. 5), the light emitting elements OLED (refer to FIG. 5) of the first pixel, the second pixel, and the third pixel may emit source lights having a same color. However, the light emitting elements OLED (refer to FIG. 5) of the first pixel, the second pixel, and the third pixel may have a same size or different sizes.

The source lights generated by the light emitting elements OLED (refer to FIG. 5) of the first pixel, the second pixel, and the third pixel may be converted to lights having different colors while passing through the first pixel area PXA-R, the second pixel area PXA-G, and the third pixel area PXA-B and may be emitted. The source light generated by the first display substrate 100 may be converted to the light having a color different from the color of the source light in the second display substrate 200 (refer to FIG. 5) described below.

The first pixel area PXA-R and the third pixel area PXA-B may be arranged in the same row, and the second pixel area PXA-G may be arranged in a row different from the row in which the first pixel area PXA-R and the third pixel area PXA-B are arranged. The second pixel area PXA-G may have the largest size in a plan view, and the third pixel area PXA-B may have the smallest size in a plan view, however, the disclosure should not be limited thereto or thereby. In an embodiment, each of the first pixel area PXA-R, the second pixel area PXA-G, and the third pixel area PXA-B may have a substantially square shape in a plan view, however, the arrangement and size of the pixel areas should not be particularly limited.

The arrangement of the first pixel area PXA-R, the second pixel area PXA-G, and the third pixel area PXA-B disposed in the unit pixels PXU shown in FIG. 4 is merely an embodiment, and the disclosure should not be limited thereto or thereby. According to an embodiment, the first pixel area PXA-R, the second pixel area PXA-G, and the third pixel area PXA-B may be arranged in the same row along the first direction DR1. The arrangement of the first pixel area PXA-R, second pixel area PXA-G, and third pixel area PXA-B may be changed depending on the unit pixels PXU.

FIG. 5 is a schematic cross-sectional view of the display device DD taken along line I-I′ of FIG. 4.

FIG. 5 schematically shows a cross-section of portions of the first, second, and third pixel areas PXA-R, PXA-G, and PXA-B of the display device DD taken along line I-I′ of FIG. 4.

The first display substrate 100 may include a first base layer BS1, a circuit layer CL, a display element layer EDL, an encapsulation layer TFE, and a light control layer CCL.

The first base layer BS1 may be disposed at a lowermost position of the first display substrate 100. The first base layer BS1 may provide a base surface on which components except the first base layer BS1 included in the first display substrate 100 are stacked.

The first base layer BS1 may include a synthetic resin layer or a glass layer. The first base layer BS1 may include a first synthetic resin layer, a second synthetic resin layer, and an inorganic layer disposed between the first and second synthetic resin layers. The synthetic resin layer may include a thermosetting resin. For example, the synthetic resin layer may be a polyimide-based resin layer, however, the disclosure should not be limited thereto or thereby. The synthetic resin layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin.

The circuit layer CL may be disposed on the first base layer BS 1. The circuit layer CL may include an insulating layer, a semiconductor pattern, a conductive pattern, and a signal line. An insulating layer, a semiconductor layer, and a conductive layer may be formed on the first base layer BS1 by a coating or depositing process. The insulating layer, the semiconductor layer, and the conductive layer may be selectively patterned through several photolithography processes. Accordingly, the semiconductor pattern, the conductive pattern, and the signal line may be formed in the circuit layer CL. The circuit layer CL may include a transistor, a buffer layer, and multiple insulating layers.

The display element layer EDL may be disposed on the circuit layer CL and may include a light emitting element OLED and a pixel definition layer PDL.

The light emitting element OLED may include a first electrode AE, a second electrode CE facing the first electrode AE, and a light emitting layer EML disposed between the first electrode AE and the second electrode CE. The light emitting layer EML included in the light emitting element OLED may include an organic light emitting material or a quantum dot as a light emitting material. The light emitting element OLED may further include a hole transport region HTR and/or an electron transport region ETR.

The pixel definition layer PDL may be disposed on the circuit layer CL and may cover a portion of the first electrode AE. Light emitting openings OH may be defined in the pixel definition layer PDL. At least a portion of the first electrode AE may be exposed through a corresponding light emitting opening of the light emitting openings OH of the pixel definition layer PDL.

First, second, and third light emitting areas EA1, EA2, and EA3 may be defined to correspond to portions of the first electrode AE, which are exposed through the light emitting openings OH of the pixel definition layer PDL. An area except the first, second, and third light emitting areas EA1, EA2, and EA3 may be defined as a non-light-emitting area. The expression “Two components correspond to each other.” may mean that the two components overlap each other in the third direction DR3 that is a thickness direction of the display device DD, but should not be limited to having the same size as each other.

The first, second, and third light emitting areas EA1, EA2, and EA3 may overlap the first, second, and third pixel areas PXA-R, PXA-G, and PXA-B in a plan view, respectively. In a plan view, sizes of the first, second, and third pixel areas PXA-R, PXA-G, and PXA-B may be greater than sizes of the first, second, and third light emitting areas EA1, EA2, and EA3, however, the disclosure should not be limited thereto or thereby. In another embodiment, the sizes of the pixel areas PXA-R, PXA-G, and PXA-B and the sizes of the light emitting areas EA1, EA2, and EA3 in a plan view may be substantially the same.

The first electrode AE may be disposed on the circuit layer CL. The first electrode AE may be an anode or a cathode. According to an embodiment, the first electrode AE may be a pixel electrode, or the first electrode AE may be a transmissive electrode, a transflective electrode, or a reflective electrode.

The hole transport region HTR may be disposed on the first electrode AE. The hole transport region HTR may be commonly disposed in the first, second, and third light emitting areas EA1, EA2, and EA3 and the non-light-emitting area. A common layer such as the hole transport region HTR may be disposed to overlap the unit pixels PXU in a plan view in the display area DA shown in FIG. 4, however, the disclosure should not be limited thereto or thereby. According to an embodiment, the hole transport region HTR may be divided into multiple portions to be respectively correspond to the first, second, and third light emitting areas EA1, EA2, and EA3. The hole transport region HTR may include at least one of a hole transport layer, a hole injection layer, and an electron blocking layer.

The light emitting layer EML may be disposed on the hole transport region HTR. The light emitting layer EML may be commonly disposed in the first, second, and third light emitting areas EA1, EA2, and EA3 and the non-light-emitting area. The light emitting layer EML may be disposed to entirely overlap the hole transport region HTR and the electron transport region ETR in a plan view, however, the disclosure should not be limited thereto or thereby. According to an embodiment, the light emitting layer EML may be disposed in the light emitting opening OH. For example, the light emitting layer EML may be divided into multiple portions to be respectively correspond to each of the first, second, and third light emitting areas EA1, EA2, and EA3, which are distinguished from each other by the pixel definition layer PDL.

The light emitting layer EML may generate the source light. In the display device DD, the light emitting layer EML may emit a blue light, and thus, the blue light may be the source light. In an embodiment that the light emitting layer EML is divided into multiple portions corresponding to the first, second, and third light emitting areas EA1, EA2, and EA3, all the first, second, and third light emitting areas EA1, EA2, and EA3 of the light emitting layer EML may emit the blue light, or the first, second, and third light emitting areas EA1, EA2, and EA3 may emit lights in different wavelengths ranges from each other.

The light emitting layer EML may have a single-layer structure of a single material, a single-layer structure of different materials, or a multi-layer structure of layers formed of different materials. The light emitting layer EML may include a fluorescent or phosphorescent material. According to an embodiment, the light emitting layer EML of the light emitting element may include an organic light emitting material, a metal organic complex, or a quantum dot as a light emitting material.

The electron transport region ETR may be disposed on the light emitting layer EML. The electron transport region ETR may include at least one of an electron injection layer, an electron transport layer, and a hole blocking layer. The electron transport region ETR may be disposed as a common layer to entirely overlap the first, second, and third light emitting areas EA1, EA2, and EA3 and the pixel definition layer PDL in a plan view, however, the disclosure should not be limited thereto or thereby. According to an embodiment, the electron transport region ETR may be divided into multiple portions, and the divided portions of the electron transport region ETR may be arranged to respectively correspond to the first, second, and third light emitting areas EA1, EA2, and EA3.

The second electrode CE may be disposed on the electron transport region ETR. The second electrode CE may be a common electrode. The second electrode CE may be a cathode or an anode, however, the disclosure should not be limited thereto or thereby. For example, in case that the first electrode AE is an anode, the second electrode CE may be a cathode, and in case that the first electrode AE is a cathode, the second electrode CE may be an anode. The second electrode CE may be a transmissive electrode, a transflective electrode, or a reflective electrode.

The encapsulation layer TFE may be disposed on the display element layer EDL. The encapsulation layer TFE may be commonly disposed in the unit pixels PXU (refer to FIG. 4). The encapsulation layer TFE may include a first inorganic layer INL1, an organic layer OL, and a second inorganic layer INL2, however, the disclosure should not be limited thereto or thereby. The encapsulation layer TFE may further include multiple inorganic layers and multiple organic layers. The encapsulation layer TFE may prevent external moisture or oxygen from entering the light emitting layer EML and may prevent reliability of the display device DD from being deteriorated.

The first inorganic layer INL1 may be disposed on the second electrode CE. The first inorganic layer INL1 may prevent the external moisture or oxygen from entering the light emitting layer EML. The first inorganic layer INL1 may include silicon nitride, silicon oxide, or a compound thereof. The first inorganic layer INL1 may be formed through a deposition process.

The organic layer OL may be disposed on the first inorganic layer INL1. The organic layer OL may provide a flat surface on the first inorganic layer INL1. Uneven portions may be formed on the first inorganic layer INL1 or particles formed in a manufacturing process of the display device DD may remain on the first inorganic layer INL1. The organic layer OL may be disposed on the first inorganic layer INL1, and thus, the organic layer OL may prevent the uneven portions or particles on the first inorganic layer INL1 from exerting influences on the components formed on the organic layer OL. The organic layer OL may include an organic material and may be formed through a solution process, such as a spin coating process, a slit coating process, an inkjet process, or the like.

In a process of forming the organic layer OL, an overflow phenomenon in which the organic layer OL is formed beyond the display area DA (refer to FIG. 4) may occur since a solution containing an organic material has flowability. The display device DD may further include dam patterns (not shown) that restrain the flowability of the solution including an organic material, and thus, the occurrence of the overflow phenomenon may be prevented.

The second inorganic layer INL2 may be disposed on the organic layer OL and cover the organic layer OL. The second inorganic layer INL2 may include silicon nitride, silicon oxide, or a compound thereof. Since the organic layer OL provides a flat surface, the second inorganic layer INL2 may be stably formed on a relatively flat surface compared with an embodiment that the second inorganic layer INL2 is disposed on (e.g., directly disposed on) the first inorganic layer INL1. The second inorganic layer INL2 may be formed through a deposition process. A hydrogen plasma treatment may be further performed on the organic layer OL between the forming of the organic layer OL and the forming of the second inorganic layer INL2. In case that the surface of the organic layer OL is hydrogen-plasma treated, the second inorganic layer INL2 may be more uniformly formed on the organic layer OL. According to an embodiment, the second inorganic layer INL2 may have a first refractive index in a range of about 1.3 to about 1.46.

The light control layer CCL may be disposed on the encapsulation layer TFE. The light control layer CCL may include a bank BK, light control patterns CCP-R, CCP-G, and CCP-B, and a first capping layer CP1.

The bank BK may be formed on the second inorganic layer INL2. The bank BK may be provided with openings BK-OP defined therethrough. The openings BK-OP corresponding to the first, second, and third pixel areas PXA-R, PXA-G, and PXA-B may be defined as first, second, and third openings BK-OP1, BK-OP2, and BK-OP3, respectively.

The bank BK may be a pattern with a black color, e.g., a black matrix. The bank BK may include a black coloring agent. The black coloring agent may include a black dye or a black pigment. According to an embodiment, the black coloring agent may include carbon black, a metal material such as chromium, or an oxide thereof.

First, second, and third light control patterns CCP-R, CCP-G, and CCP-B may be disposed in the openings BK-OP, respectively. The first, second, and third light control patterns CCP-R, CCP-G, and CCP-B may change optical properties of the source light. For example, the first and second light control patterns CCP-R and CCP-G may absorb the source light and may generate a light having a color different from the color of the source light. The third light control pattern CCP-B may transmit or scatter a portion of the source light incident thereto. Accordingly, the light exiting through the third light control pattern CCP-B and the source light may have substantially the same color. As described above, the third light control pattern CCP-B may have an optical function different from the optical function of the first and second light control patterns CCP-R and CCP-G.

Each of the first and second light control patterns CCP-R and CCP-G may include a base resin and quantum dots mixed with (or dispersed in) the base resin. In an embodiment, the first and second light control patterns CCP-R and CCP-G may be defined as a quantum dot pattern and may include different quantum dots. The base resin may be a medium in which the quantum dots are dispersed and may include various resin compositions that are generally referred to as a binder. However, the disclosure should not be limited thereto or thereby. In the disclosure, any medium in which the quantum dots are dispersed may be used as the base resin regardless of its name, additional functions, constituent materials, etc. The base resin may be a polymer resin. For example, the base resin may be an acrylic-based resin, a urethane-based resin, a silicone-based resin, or an epoxy-based resin. The base resin may be a transparent resin.

The quantum dots may be particles that change a wavelength of light incident thereto. The quantum dots may be a material having a crystal structure of several nanometers in size, contain hundreds to thousands of atoms, and exhibit a quantum confinement effect, which results in an increased energy band gap due to their small size. In case that a light with a wavelength carrying higher energy than the band gap is incident into the quantum dots, the quantum dots absorb the light and become excited, and the quantum dots may emit a light of a specific wavelength and fall to a ground state. The emitted light of the specific wavelength may have an energy value corresponding to the band gap. The light-emitting property of the quantum dots due to the quantum confinement effect may be controlled by adjusting the size and the composition of the quantum dots. According to an embodiment, a diameter of the quantum dot may be in a range of about 1 nm to about 10 nm.

The quantum dots may be synthesized by a wet chemical process, a metal organic chemical vapor deposition process, a molecular beam epitaxy process, or similar processes. The wet chemical process may be a method of growing quantum dot particle crystals after mixing an organic solvent with a precursor material. In case that the crystals grow, the organic solvent may naturally serve as a dispersant coordinated to the surface of the quantum dot crystal and may control the growth of the crystals. Accordingly, the wet chemical process may be more readily performed than vapor deposition methods such as the metal organic chemical vapor deposition (MOCVD) process or the molecular beam epitaxy (MBE) and may control the growth of quantum dot particles through a low-cost process.

The quantum dots may include a group III-VI compound, a group II-VI compound, a group III-V compound, a group compound, a group IV-VI compound, a group IV element, a group IV compound, or a combination thereof.

The group III-VI compound may include a binary compound such as GaS, Ga2S3, GaSe, Ga2Se3, GaTe, InS, InSe, In2Se3, and/or InTe, a ternary compound such as InGaS3 and/or InGaSe3, or a combination thereof.

The group II-VI compound may include a binary compound such as CdS, CdSe, CdTe, ZnS, ZnSe, ZnTe, ZnO, HgS, HgSe, HgTe, MgSe, and/or MgS, a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and/or MgZnS, a quaternary compound such as CdZnSeS, CdZnSeTe, CdZnSTe, CdHgSeS, CdHgSeTe, CdHgSTe, HgZnSeS, HgZnSeTe, and/or HgZnSTe, or a combination thereof. The group II-VI compound may further include a group I metal and/or a group IV element. The group compound may include CuSnS or CuZnS, and the group II-IV-VI compound may include ZnSnS. The group I-II-IV-VI compound may include a quaternary compound such as Cu₂ZnSnS₂, Cu₂ZnSnS₄, Cu₂ZnSnSe₄, Ag₂ZnSnS₂, and a mixture thereof.

The group III-V compound may include a binary compound such as GaN, GaP, GaAs, GaSb, AlN, AlP, AlAs, AlSb, InN, InP, InAs, and/or InSb, a ternary compound such as GaNP, GaNAs, GaNSb, GaPAs, GaPSb, AlNP, AlNAs, AlNSb, AlPAs, AlPSb, InGaP, InNP, InAlP, InNAs, InNSb, InPAs, and/or InPSb, a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, and/or InAlPSb, or a combination thereof. The group III-V compound may further include a group II element. For instance, the group III-V compound that further includes the group II element may include InZnP, InGaZnP, InAlZnP, etc.

The group compound may include a ternary compound such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, and/or AgAlO₂, a quaternary compound such as AgInGaS₂, and/or AgInGaSe₂, or a combination thereof.

The group IV-VI compound may include a binary compound such as SnS, SnSe, SnTe, PbS, PbSe, and/or PbTe, a ternary compound such as SnSeS, SnSeTe, SnSTe, PbSeS, PbSeTe, PbSTe, SnPbS, SnPbSe, and/or SnPbTe, a quaternary compound such as SnPbSSe, SnPbSeTe, and/or SnPbSTe, or a combination thereof.

The group II-IV-V compound may include a ternary compound such as ZnSnP, ZnSnP₂, ZnSnAs₂, ZnGeP₂, ZnGeAs₂, CdSnP₂, CdGeP₂, and a mixture thereof.

The group IV element or the group IV compound may include a single-element compound such as Si or Ge, a binary compound such as SiC or SiGe, or a combination thereof.

Each element included in a multi-element compound, such as the binary compound, the ternary compound, or the quaternary compound, may be present in the particles at a uniform or non-uniform concentration. For example, the above chemical formula means the types of elements included in the compound, and an element ratio in the compound may be variable. For example, AgInGaS₂ may be AgInₓGa₁₋ₓS₂ (x is a real number between 0 to 1).

The quantum dot may have a single structure in which the concentration of each element in the quantum dot is substantially uniform, or a core-shell dual structure. For example, a material included in the core and a material included in the shell may be different from each other.

The shell of the quantum dot may serve as a protective layer to prevent chemical modification of the core and to maintain semiconductor properties and/or may serve as a charging layer to impart electrophoretic properties to the quantum dot. The shell may have a single-layer or multi-layer structure. The concentration of elements existing in the shell may have the concentration gradient that is lowered as a distance from a center decreases in an interface between the core and the shell. (In the core/shell structure, the concentration of elements existing in the shell may have a concentration gradient that is lowered as a distance from the core decreases.)

The shell of the quantum dots may include a metal oxide, a non-metal oxide, a semiconductor compound, or a combination thereof. The metal oxide or non-metal oxide may include a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, a ternary compound, such as MgAl₂O₄, CoFe₂O₄, NiFe₂O₄, and CoMn₂O₄, or a combination thereof. The semiconductor compound may include the group III-VI compound, the group II-VI compound, the group III-V compound, the group compound, the group IV-VI compound, or a combination thereof. For example, the semiconductor compound may include CdS, CdSe, CdTe, ZnS, ZnSe, ZnTe, ZnSeS, ZnTeS, GaAs, GaP, GaS, GaSe, AgGaS, AgGaS2, GaSb, HgS, HgSe, HgTe, InAs, InP, InGaP, InSb, AlAs, AlP, AlSb, or a combination thereof.

Each element included in a multi-element compound, such as the binary compound, or the ternary compound, may be present in the particles at a uniform or non-uniform concentration. For example, the above chemical formula means the types of elements included in the compound, and an element ratio in the compound may be variable.

The quantum dots may have a full width at half maximum (FWHM) of a light emission wavelength spectrum less than or equal to about 45 nm. For example, a full width at half maximum (FWHM) of a light emission wavelength spectrum of the quantum dot may be less than or equal to about 40 nm. For example, a full width at half maximum (FWHM) of a light emission wavelength spectrum of the quantum dot may be less than or equal to about 30 nm. The color purity and the color reproducibility may be improved within this range. Since the light emitted through the quantum dots may be emitted in all directions, an optical viewing angle may be improved.

The quantum dots may have a spherical shape, a pyramidal shape, a multi-arm shape, or cubic nanoparticles, nanotubes, nanowires, nanofibers, nanoplatelets, or the like.

Since the energy band gap may be adjusted by controlling the size of the quantum dot or the element ratio in the compounds of the quantum dot, lights having one or more suitable wavelengths may be obtained from a quantum dot light-emitting layer. Accordingly, as the quantum dots described above, i.e., the quantum dots having different sizes or having the compounds with different element ratios, are used, the light emitting element that emits the lights of one or more suitable wavelengths may be implemented. For example, the size of the quantum dot and the element ratio of the compounds of the quantum dot may be selected to emit the red, green and/or blue lights. The quantum dot may be configured to emit a white light by combination of the lights having various colors.

According to an embodiment, the first light control pattern CCP-R may be a red quantum dot pattern that absorbs the source light and generates the red light, and the second light control pattern CCP-G may be a green quantum dot pattern that absorbs the source light and generates the green light. The first light control pattern CCP-R and the second light control pattern CCP-G may further include scattering particles.

The third light control pattern CCP-B may include scattering particles mixed with (or dispersed in) the organic material. The third light control pattern CCP-B may be a scattering pattern that scatters the source light. The scattering particles may be particles having a relatively large density or specific gravity. The scattering particles may include titanium oxide (TiO₂) or silica-based nanoparticles.

The first capping layer CP1 may be disposed on the bank BK and the first, second, and third light control patterns CCP-R, CCP-G, and CCP-B. The first capping layer CP1 may encapsulate the bank BK and the first, second, and third light control patterns CCP-R, CCP-G, and CCP-B and prevent the bank BK and the first, second, and third light control patterns CCP-R, CCP-G, and CCP-B from being damaged in the subsequent process. The first capping layer CP1 may have a single-layer or multi-layer structure. The first capping layer CP1 may include silicon oxide, silicon nitride, silicon oxynitride, or the like.

The second display substrate 200 may include a second base layer BS2, a color filter layer CFL, a low refractive index layer LR, and a second capping layer CP2.

The second display substrate 200 may be disposed above the first display substrate 100 and may be spaced apart from the first display substrate 100. The cell gap GP may be a space between the first display substrate 100 and the second display substrate 200 spaced apart from the first display substrate 100. The cell gap GP may be maintained in an empty space or may be filled with a gas. The cell gap GP may be filled with a filling member FML. The filling member FML may include an epoxy-based organic material.

The second base layer BS2 may provide a base surface on which the color filter layer CFL is disposed. The second base layer BS2 may include a synthetic resin layer or a glass layer. The synthetic resin layer may include a thermosetting resin. The synthetic resin layer may be a polyimide-based resin layer, however, the disclosure should not be limited thereto or thereby. The synthetic resin layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. The second base layer BS2 may include a glass substrate, a metal substrate, or an organic/inorganic composite material substrate.

The color filter layer CFL may be disposed on a lower surface of the second base layer BS2. The color filter layer CFL may include color filters CF-1, CF-2, and CF-3. The color filters CF-1, CF-2, and CF-3 may include first, second, and third color filters CF-1, CF-2, and CF-3 respectively overlapping the first, second, and third pixel areas PXA-R, PXA-G, and PXA-B in a plan view. The first, second, and third color filters CF-1, CF-2, and CF-3 may be a red color filter, a green color filter, and a blue color filter, respectively.

The first pixel area PXA-R, the second pixel area PXA-G, the third pixel area PXA-B, and the peripheral area NPXA may be defined by the first, second, and third color filters CF-1, CF-2, and CF-3. The peripheral area NPXA may be defined as an area where two or more color filters of the first, second, and third color filters CF-1, CF-2, and CF-3 overlap each other in a plan view. The first pixel area PXA-R may overlap only the first color filter CF-1, the second pixel area PXA-G may overlap only the second color filter CF-2, and the third pixel area PXA-B may overlap only the third color filter CF-3.

In case that two or more color filters overlap each other, the effect of blocking the external light may increase, and the interference of colors or the color mixture between the pixels may be prevented. Therefore, the structure in which two or more color filters overlap each other may correspond to a light blocking structure.

A filter opening may be defined through the second color filter CF-2 and the third color filter CF-3 to correspond to the first pixel area PXA-R Similarly, a filter opening may be defined through the first color filter CF-1 and the third color filter CF-3 to correspond to the second pixel area PXA-G, and a filter opening may be defined through the first color filter CF-1 and the second color filter CF-2 to correspond to the third pixel area PXA-B.

The low refractive index layer LR may be disposed under the color filter layer CFL. The low refractive index layer LR may be disposed on the light control layer CCL. The low refractive index layer LR may be disposed between the light control layer CCL and the color filter layer CFL to serve as an optical functional layer that improves a light extraction efficiency or prevents a reflected light from being incident into the light control layer CCL. The low refractive index layer LR may have a refractive index smaller than the refractive index of a layer adjacent thereto. For example, the low refractive index layer LR may have a refractive index equal to or smaller than about 1.45.

The second display substrate 200 may further include the second capping layer CP2. The second capping layer CP2 may be disposed on a lower surface of the low refractive index layer LR. In an embodiment, the low refractive index layer LR may be omitted from the second display substrate 200, and the second capping layer CP2 may be in contact with (e.g., directly contact with) the first, second, and third color filters CF-1, CF-2, and CF-3. The second capping layer CP2 may serve as a protective layer that covers the color filters CF-1, CF-2, and CF-3 and prevents the color filters CF-1, CF-2, and CF-3 from being damaged in the manufacturing process of the display device DD. In an embodiment, the second capping layer CP2 may be omitted from the second display substrate 200.

The second display substrate 200 may further include a step-difference compensation layer (not shown). The step-difference compensation layer (not shown) may be disposed on a lower surface of the second capping layer CP2 overlapping the non-display area NDA (refer to FIG. 2) in a plan view. The step-difference compensation layer (not shown) may compensate for a step difference occurring in the second display substrate 200 during processes of forming the first, second, and third color filters CF-1, CF-2, and CF-3 and the second capping layer CP2. Accordingly, the sealing member SLM (refer to FIG. 2) may be disposed on the flat surface provided by the step-difference compensation layer (not shown), and thus, the second display substrate 200 and the first display substrate 100 may be bonded with each other through a vacuum-pressure process.

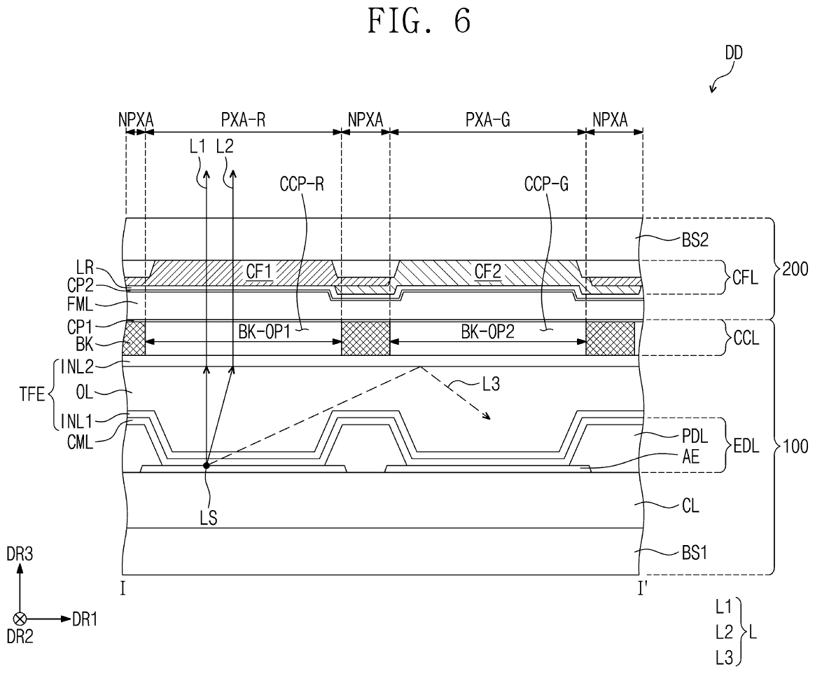

FIG. 6 is a schematic cross-sectional view of the display device DD according to an embodiment of the disclosure. FIG. 6 shows the first pixel area PXA-R and the second pixel area PXA-G of the display device DD shown in FIG. 5.

Hereinafter, the display device DD will be described with reference to FIG. 6. In FIG. 6, the same/similar reference numerals denote the same/similar elements in FIG. 5, and thus, detailed descriptions of the same/similar elements will be omitted.

FIG. 6 is an enlarged cross-sectional view of the first pixel area PXA-R and the second pixel area PXA-G among the pixel areas PXA-R, PXA-G, and PXA-B shown in FIG. 5. In FIG. 6, the hole transport region HTR (refer to FIG. 5), the light emitting layer EML (refer to FIG. 5), the electron transport region ETR (refer to FIG. 5), and the second electrode CE (refer to FIG. 5) are simply illustrated as a single common layer CML.

In case that electrons are combined with holes in the light emitting layer EML (refer to FIG. 5) of the common layer CML, a light source LS in the light emitting layer EML (refer to FIG. 5) may emit a light L. FIG. 6 shows a structure in which the light source LS in the light emitting layer EML (refer to FIG. 5) overlapping the first pixel area PXA-R in a plan view emits the light L.

According to an embodiment, the light L may be refracted at an interface between the second inorganic layer INL2 and the organic layer OL. The refractive index of the organic layer OL and the second inorganic layer INL2 may be limited to a specific range to improve the color mixture of light. The first refractive index of the second inorganic layer INL2 may be in a range of about 1.3 to about 1.46. The organic layer OL may have a second refractive index greater than the first refractive index. For example, the second refractive index of the organic layer OL may be in a range of about 1.5 to about 1.7.

The second inorganic layer INL2 may have a thickness in a range that refracts the light L while not excessively increasing an overall thickness of the display device DD. For example, the thickness of the second inorganic layer INL2 may be in a range of about 400 nm to about 2000 nm, however, the disclosure should not be limited thereto or thereby.

Since light has a divergence, the light L emitted from the light source LS may spread out in all directions. FIG. 6 shows a first light L1, a second light L2, and a third light L3 of the light L emitted from the light source LS.

The first light L1 may be a light that travels to the first opening BK-OP1 and incidents perpendicular to the interface between the organic layer OL and the second inorganic layer INL2. Since a light incident perpendicular to an interface of two materials with different refractive indices is not refracted at the interface between the two materials, the first light L1 may not be refracted at the interface between the organic layer OL and the second inorganic layer INL2. Accordingly, the first light L1 may reach the first opening BK-OP1 and may be affected by the light control pattern CCP included in the first opening BK-OP1. For example, light control pattern CCP may include a first light control pattern CCP-R, a second light control pattern CCP-G, and a third light control pattern CCP-B. In case that the first light control pattern CCP-R included in the first opening BK-OP1 is the red quantum dot pattern, the first light control pattern CCP-R may absorb the first light L1, may generate the red light, and may emit the red light.

The second light L2 may be a light that travels to the first opening BK-OP1 and incidents obliquely to the interface between the organic layer OL and the second inorganic layer INL2. Since a light incident obliquely to an interface between two materials with difference refractive indices is refracted at the interface between two materials, the second light L2 may be refracted at the interface between the organic layer OL and the second inorganic layer INL2. However, since the degree of refraction of the second light L2 is not large as shown in FIG. 6, the second light L2 may reach the first opening BK-OP1 like the first light L1 and may be affected by the light control pattern CCP included in the first opening BK-OP1. For example, in case that the first light control pattern CCP-R included in the first opening BK-OP1 is the red quantum dot pattern, the first light control pattern CCP-R may absorb the second light L2, may generate the red light, and may emit the red light.

The third light L3 may be defined as a light that leaks to the second opening BK-OP2 adjacent to the first opening BK-OP1 instead of traveling to the first opening BK-OP1 overlapping the light source LS in a plan view. In case that a light traveling through a medium with a high refractive index enters a medium with a low refractive index and an incident angle is greater than a critical angle of total reflection, a total reflection may occur at a boundary of two media. Accordingly, the third light L3 may be totally reflected at the interface between the organic layer OL and the second inorganic layer INL2, and thus, a direction to which the third light L3 travels may be changed. The third light L3 may not reach the second light control pattern CCP-G included in the second opening BK-OP2, and thus, the green light may be reduced. Therefore, the color mixture between the red light and the green light may be improved.

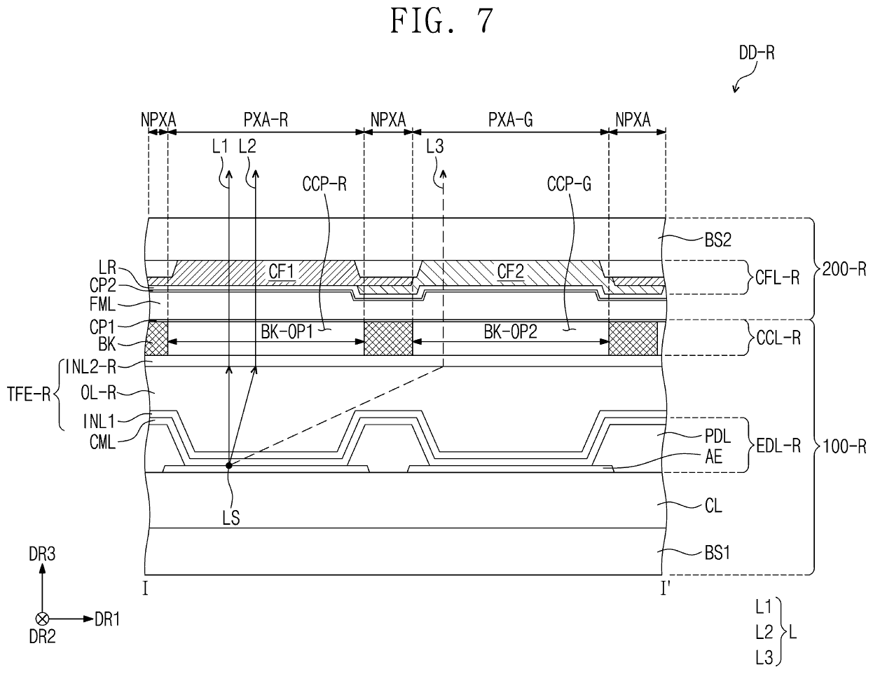

FIG. 7 is a schematic cross-sectional view of a display device DD-R according to a comparative example. The display device DD-R according to the comparative example will be described with reference to FIG. 7. In FIG. 7, the same/similar reference numerals denote the same/similar elements in FIG. 4, and thus, detailed descriptions of the same/similar elements will be omitted.

The display device DD-R according to the comparative example includes a first display substrate 100-R and a second display substrate 200-R. The second display substrate 200-R is disposed above and spaced apart from the first display substrate 100-R. A filling member FML is filled in between the first display substrate 100-R and the second display substrate 200-R. The filling member FML covers a first capping layer CP1.

The first display substrate 100-R includes a first base layer BS1, a circuit layer CL, a display element layer EDL-R, an encapsulation layer TFE-R, a light control layer CCL-R, and the first capping layer CP1.

Descriptions of the first base layer BS1-R, the circuit layer CL, the display element layer EDL-R, the encapsulation layer TFE-R, the light control layer CCL-R, and the first capping layer CP1 correspond to those in FIG. 5. In FIG. 7, for the convenience of explanation, the hole transport region HTR (refer to FIG. 5), the light emitting layer EML (refer to FIG. 5), the electron transport region ETR (refer to FIG. 5), and the second electrode CE (refer to FIG. 5) are simply illustrated a single common layer CML-R.

The second display substrate 200-R includes a second base layer BS2, a color filter layer CFL-R, and a low refractive index layer LR.

Descriptions of the second base layer BS2-R, the color filter layer CFL-R, and the low refractive index layer LR correspond to those in FIG. 5.

In case that electrons are combined with holes in the light emitting layer EML (refer to FIG. 5) of the common layer CML-R, a light source LS in the light emitting layer EML (refer to FIG. 5) emits a light L. FIG. 7 shows a structure in which the light source LS in the light emitting layer EML (refer to FIG. 5) overlapping a first pixel area PXA-R in a plan view emits the light L.

According to the display device DD-R, the light L is refracted at an interface between a second inorganic layer INL2-R and an organic layer OL-R. The organic layer OL-R has a second refractive index smaller than a first refractive index of the second inorganic layer INL2-R.

FIG. 7 shows a first light L1, a second light L2, and a third light L3 of the light L. However, lights light L should not be limited thereto or thereby.

Descriptions on the traveling and refraction of the first light L1 and the second light L2 substantially correspond to the traveling and refraction of the first light L1 and the second light L2 described with reference to FIG. 6, and thus, details thereof will be omitted.

The third light L3 is a portion of the light L, which travels to a second opening BK-OP2 adjacent to a first opening BK-OP1 instead of traveling to the first opening BK-OP1 overlapping the light source LS in a plan view.

In the comparative example, the refractive index of the second inorganic layer INL2-R has a value range different from the refractive index of the second inorganic layer INL2 in the disclosure. For example, the first refractive index of the second inorganic layer INL2-R is greater than about 1.46. The first refractive index of the second inorganic layer INL2-R is greater than the second refractive index of the organic layer OL-R.

In case that a light traveling through a medium with a low refractive index enters a medium with a high refractive index, the third light L3 is refracted toward a direction in which the medium having the high refractive index is placed. FIG. 7 shows a case where the third light L3 is refracted to a left side of its traveling direction. However, FIG. 7 schematically represents the traveling direction of the light, and an angle of the refraction of the light is slightly exaggerated.

In case that the third light L3 reaches the second opening BK-OP2 and is affected by a second light control pattern CCP-G included in the second opening BK-OP2, a green light may be consequently generated and emitted. Accordingly, even in the case where only the red light is expected to be emitted from the unit pixel PXU (refer to FIG. 4), the green light is also emitted. Thus, the color mixture between the green light and the red light occurs.

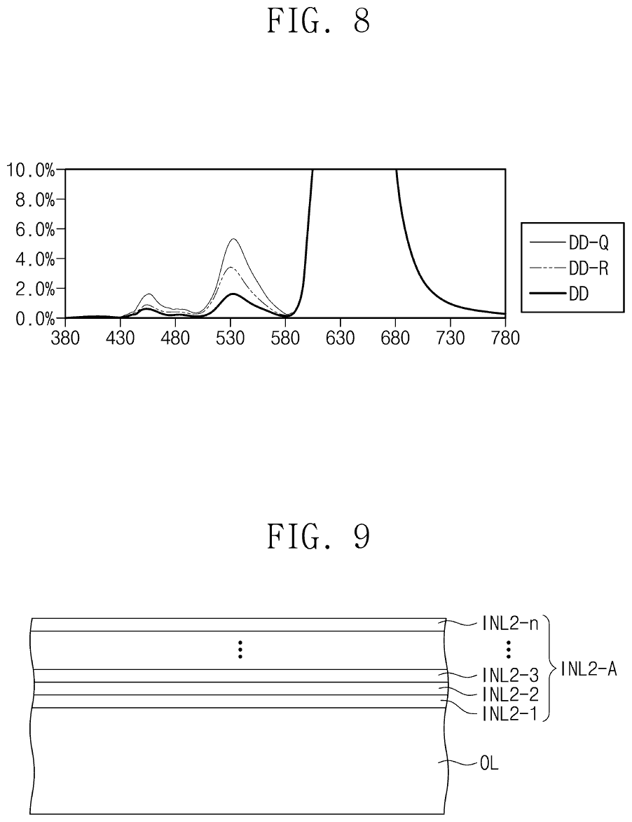

FIG. 8 is a graph illustrating an intensity of a light as a function of a wavelength.

FIG. 8 is a graph analyzing lights actually emitted from three types of display devices DD-Q, DD-R, and DD in case that the red light is expected to be emitted from three types of display devices DD-Q, DD-R, and DD. In the graph of FIG. 8, an x-axis represents a wavelength (nm) of the lights emitted from each display device. A y-axis of the graph represents an intensity of other lights as relative values in case that an intensity of the strongest red light is set as 100%. In the graph of FIG. 8, a peak around the wavelength of about 530 nm shows a degree of the color mixture of the green light to the red light. The higher the peak around the wavelength of about 530 nm, the greater the degree of color mixture of the green light.

Different from the disclosure, the display device DD-Q is a display device in which a light control layer is disposed under a second display substrate. The display device DD-R has the structure in which the light control layer CCL-R (refer to FIG. 7) is disposed on the first display substrate 100-R (refer to FIG. 7), however, the refractive index of the second inorganic layer INL2-R (refer to FIG. 7) included in the display device DD-R is different from the refractive index of the second inorganic layer INL2 (refer to FIG. 5) of the disclosure. The display device DD has the structure in which the light control layer CCL (refer to FIG. 5) is disposed on the first display substrate 100 and the second inorganic layer INL2 (refer to FIG. 5) has the refractive index of about 1.46 and the thickness of about 400 nm.

Referring to FIG. 8, the color mixture of the green light to the red light is the largest in the display device DD-Q, the color mixture of the green light to the red light is the next largest in the display device DD-R, and the color mixture of the green light to the red light is the smallest in the display device DD.

Since the light control layer is included in the second display substrate in the display device DD-Q, it is most likely that the light emitted from the display element layer diverges and leaks into the light control pattern adjacent thereto rather than the light control pattern overlapping therewith.

On the other hand, since the light control layer CCL-R (refer to FIG. 7) is included in the first display substrate 100-R (refer to FIG. 7) in the display device DD-R, a distance between the display element layer PDL-R (refer to FIG. 7) and the light control layer CCL-R (refer to FIG. 7) may be smaller than that in the display device DD-Q. Accordingly, a rate of the light L (refer to FIG. 7) emitted from the display element layer EDL-R (refer to FIG. 7) toward the overlapping light control layer CCL-R (refer to FIG. 7) is higher, and thus, it may be inferred that the color mixture caused by the green light is slightly reduced than in the display device DD-Q.

In the display device DD, although the distance between the display element layer PDL (refer to FIG. 5) and the light control layer CCL (refer to FIG. 5) is the same as that of the display device DD-R, it may be inferred that the color mixture caused by the green light is further reduced by adjusting the refractive index and thickness of the second inorganic layer INL2 (refer to FIG. 5).

FIG. 8 shows the color mixture of the green light with respect to a red light spectrum, however, this is merely an example, and a blue light spectrum or a green light spectrum may be substantially the same as the red light spectrum.

FIG. 9 is a schematic cross-sectional view of a second inorganic layer and an organic layer according to an embodiment of the disclosure. For the convenience of explanation, FIG. 9 schematically shows only the cross-section of the second inorganic layer INL2-A and the organic layer OL in an embodiment that the second inorganic layer INL2-A includes multiple layers in the display device DD (refer to FIG. 5).

Hereinafter, the second inorganic layer INL2-A and the organic layer OL will be described with reference to FIG. 9. According to an embodiment, the second inorganic layer INL2-A of the display device DD may include multiple layers. For example, the layers may include n inorganic layers INL2-1, INL2-2, INL2-3, . . . , and INL2-n. In the embodiment, the n is a natural number.

One of the layers may have a first refractive index, and another one of the layers may have a refractive index different from the first refractive index. For example, the another one of the layers may have a refractive index greater than the first refractive index. The first refractive index may be in a range of about 1.3 to about 1.46. The organic layer OL may have a second refractive index greater than the first refractive index. For example, the second refractive index of the organic layer OL may be in a range of about 1.5 and to about 1.7. The layer having the first refractive index may have a thickness in a range of about 400 nm to about 2000 nm.

Even though the second inorganic layer INL2-A of the display device DD (refer to FIG. 5) includes multiple layers, the traveling and refraction of the light L (refer to FIG. 6) may be substantially the same as the first light L1 (refer to FIG. 6), the second light L2 (refer to FIG. 6), and the third light L3 (refer to FIG. 6).

However, an interface at which the third light L3 (refer to FIG. 6) is totally reflected may be an interface between the inorganic layer having the first refractive index and another inorganic layer disposed under the inorganic layer having the first refractive index. However, in a case where the inorganic layer having the first refractive index corresponds to a layer disposed at the lowermost position in the layers included in the second inorganic layer INL2-A, the total reflection may occur at the interface between the inorganic layer having the first refractive index and the organic layer OL. Accordingly, the color mixture caused by the lights may be improved.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a first display substrate comprising a first base layer comprising a display area and a non-display area adjacent to the display area; and
a second display substrate comprising a second base layer comprising pixel areas overlapping the display area in a plan view and a peripheral area surrounding the pixel areas, wherein
the first display substrate further comprises:
light emitting elements respectively overlapping the pixel areas in a plan view;
an encapsulation layer comprising a first inorganic layer covering the light emitting elements, an organic layer disposed on the first inorganic layer, and a second inorganic layer disposed on the organic layer;
a bank disposed on the encapsulation layer and including openings respectively overlapping the pixel areas in a plan view; and
light control patterns respectively disposed in the openings, and
the second inorganic layer has a first refractive index in a range of about 1.3 to about 1.46.

2. The display device of claim 1, wherein the organic layer has a second refractive index greater than the first refractive index.

3. The display device of claim 2, wherein the second refractive index is in a range of about 1.5 to about 1.7.

4. The display device of claim 1, wherein a thickness of the second inorganic layer is in a range of about 400 nm to about 2000 nm.

5. The display device of claim 1, wherein
the second inorganic layer further comprises a plurality of layers,
one of the plurality of layers has the first refractive index, and
others of the plurality of layers have a refractive index different from the first refractive index.

6. The display device of claim 5, wherein the others of the plurality of layers have a refractive index greater than the first refractive index.

7. The display device of claim 1, wherein the light emitting elements emit a blue light.

8. The display device of claim 1, wherein one of the light control patterns comprises an organic material comprising a metal oxide.

9. The display device of claim 8, wherein another one of the light control patterns comprises a quantum dot.

10. The display device of claim 1, wherein the second display substrate is disposed above the first display substrate.

11. The display device of claim 10, further comprising:
a filling member filled between the first display substrate and the second display substrate.

12. The display device of claim 10, further comprising:
a sealing member overlapping the non-display area in a plan view and disposed between the first display substrate and the second display substrate.

13. The display device of claim 1, wherein the second display substrate further comprises a low refractive index layer disposed under the second base layer.

14. The display device of claim 13, wherein the second display substrate further comprises a second capping layer disposed under the low refractive index layer and covering the low refractive index layer.

15. The display device of claim 1, further comprising:
a first capping layer covering the bank and the light control patterns.

16. The display device of claim 1, wherein the second inorganic layer comprises a silicon oxide.

17. The display device of claim 1, wherein the second inorganic layer comprises a silicon oxynitride.

18. The display device of claim 1, wherein the second display substrate further comprises color filters disposed on the second base layer.

19. The display device of claim 18, wherein the color filters comprise a first color filter, a second color filter, and a third color filter.

20. The display device of claim 19, wherein two or more of the first, second, and third color filters overlap with each other in a plan view in the peripheral area.
